(19) United States
(12) Patent Application Publication
(10) Pub. No.: US 2024/0405063 A1
(43) Pub. Date: Dec. 5, 2024

(54) SEMICONDUCTOR STRUCTURE

(71) Applicant: Enkris Semiconductor (Wuxi), Ltd., Wuxi (CN)

(72) Inventor: Kai CHENG, Wuxi (CN)

(73) Assignee: Enkris Semiconductor (Wuxi), Ltd., Wuxi (CN)

(21) Appl. No.: 18/347,504

(22) Filed: Jul. 5, 2023

(30) Foreign Application Priority Data
May 31, 2023 (CN) 202310632452.0

(51) Int. Cl. H01L 29/06; H01L 29/20; H01L 29/778

(52) U.S. Cl. CPC H01L 29/0607; H01L 29/2003; H01L 29/778

(57) ABSTRACT

A semiconductor structure includes a supporting substrate, a buried layer, a growth substrate, a buffer layer, and a heterojunction structure layer that are sequentially stacked; a plurality of recesses are disposed on a side, away from the supporting substrate, of the growth substrate, and the buffer layer completely covers a surface of the growth substrate. In the present disclosure, the recesses are disposed in the growth substrate, so that a parasitic circuit formed in the growth substrate caused by a radio frequency signal may be blocked, to reduce a disturbance effect of the growth substrate, thereby reducing an RF loss; and the buffer layer is formed, by using epitaxial lateral overgrowth, in the recesses of the growth substrate, so that dislocation density in an epitaxial layer may be greatly reduced, to improve crystal quality, thereby improving characteristics such as electron mobility, breakdown voltage, and leakage current of a device.

### CROSS-REFERENCE TO RELATED APPLICATIONS

The present application claims the priority of Chinese Patent Application No. 202310632452.0, filed on May 31, 2023, the entire contents of which are incorporated herein by reference.

### TECHNICAL FIELD

The present disclosure relates to the field of semiconductor technologies, and in particular, to a semiconductor structure.

### BACKGROUND

As a typical representative of third-generation semiconductor materials, wide band gap semiconductor materials, such as group III nitrides, have excellent characteristics such as a wide band gap, high voltage resistance, high temperature resistance, high electron saturation speed and high electron drift speed, and easy to form a high-quality heterojunction structure, and many devices made of the group III nitrides may be applied to applications of high-frequency radio frequency (RF) and/or high-power.

An RF loss is an important factor affecting a linearity of RF devices.

### SUMMARY

The purposes of the present disclosure are to provide a semiconductor structure, so as to solve a technical problem in related technologies that a linearity of a radio frequency device is decreased due to an RF loss of the radio frequency device.

According to an aspect of the present disclosure, an embodiment of the present disclosure provides a semiconductor structure, including: a supporting substrate, a buried layer, a growth substrate, a buffer layer, and a heterojunction structure layer that are sequentially stacked; a plurality of recesses are disposed on a side, away from the supporting substrate, of the growth substrate, and the buffer layer completely covers a surface of the growth substrate.

In an optional embodiment, the buffer layer is conformally disposed on the growth substrate, and the buffer layer is provided with a plurality of pits that are in a one-to-one correspondence with the plurality of recesses.

In an optional embodiment, the buffer layer completely fills the plurality of recesses, and a surface of a side, away from the growth substrate, of the buffer layer is a plane.

In an optional embodiment, the growth substrate is a double layer structure, and the double layer structure includes a first sub-layer and a second sub-layer that are stacked in a direction away from the supporting substrate.

In an optional embodiment, a conductive type of the first sub-layer is an n type, and a conductive type of the second sub-layer is a p type.

In an optional embodiment, conductive types of the first sub-layer and the second sub-layer are an n type, and the first sub-layer has a doping concentration lower than that of the second sub-layer.

In an optional embodiment, a thickness of the second sub-layer is less than a depth of each recess.

In an optional embodiment, the semiconductor structure further includes: a source electrode, a drain electrode, and a gate electrode which is disposed between the source electrode and the drain electrode, and the source electrode, the drain electrode, and the gate electrode are all disposed on the heterojunction structure layer.

In an optional embodiment, shapes of projections, on a plane in which the growth substrate is located, of the plurality of recesses, are a plurality of strip shapes that are parallel to each other, and an extension direction of each strip shape is parallel to a width direction of the gate electrode.

In an optional embodiment, the plurality of recesses are evenly distributed on the growth substrate, and shapes of projections, on a plane in which the growth substrate is located, of the plurality of recesses include at least one of a triangle, a square, a hexagon, or a circle.

In an optional embodiment, in a direction perpendicular to a plane in which the growth substrate is located, cross-sectional shapes of the plurality of recesses include at least one of a rectangle, a trapezoid, an irregular quadrilateral, a triangle, a bowl, or an arc.

In an optional embodiment, each recess is in an inclined column shape.

In an optional embodiment, in a direction from the supporting substrate to the growth substrate, a line connecting centers of a plurality of cross-sections of each recess is one of a straight line, a polyline, or a curve.

In an optional embodiment, in a direction from the supporting substrate to the growth substrate, a variation trend of areas of the plurality of cross-sections of each recess includes one of the following: first increasing and then decreasing, gradually decreasing, or constant.

In an optional embodiment, a depth of each recess is less than a thickness of the growth substrate.

In an optional embodiment, materials of the supporting substrate and the growth substrate, include silicon.

In an optional embodiment, a material of the buried layer includes at least one of a silicon oxide, a silicon nitride, a silicon nitride oxide, or an aluminum nitride.

In an optional embodiment, a material of the buffer layer includes a group III nitride material.

In an optional embodiment, the semiconductor structure further includes: a nucleation layer disposed between the buffer layer and the growth substrate, and the nucleation layer is conformally formed on the growth substrate.

In an optional embodiment, in a direction away from the supporting substrate, the heterogeneous structure layer includes a channel layer and a barrier layer that are stacked, and a band gap of the barrier layer is greater than a band gap of the channel layer.

### BRIEF DESCRIPTION OF THE DRAWINGS

FIG. 1 is a schematic structural diagram of a semiconductor structure according to an embodiment of the present disclosure.

FIG. 2 is a schematic structural diagram of a semiconductor structure according to an embodiment of the present disclosure.

FIG. 3 is a schematic structural diagram of a semiconductor structure according to an embodiment of the present disclosure.

FIG. 4a to FIG. 4d are top schematic views of a growth substrate according to an embodiment of the present disclosure.

FIG. 5 is a cross-sectional schematic view of an upper surface of a growth substrate according to an embodiment of the present disclosure.

FIG. 6a to FIG. 6f are schematic structural diagrams of a semiconductor structure according to an embodiment of the present disclosure.

FIG. 7a to FIG. 7c are schematic structural diagrams of a semiconductor structure according to an embodiment of the present disclosure.

FIG. 8a to FIG. 8c are schematic structural diagrams of a semiconductor structure according to an embodiment of the present disclosure.

FIG. 9 is a schematic structural diagram of a semiconductor structure according to an embodiment of the present disclosure.

FIG. 10 is a schematic structural diagram of a semiconductor structure according to an embodiment of the present disclosure.

### DETAILED DESCRIPTION OF THE EMBODIMENTS

The following clearly and completely describes the technical solutions in embodiments of the present disclosure with reference to accompanying drawings in the embodiments of the present disclosure. Apparently, the embodiments described are merely some rather than all of the embodiments of the present disclosure. Based on the embodiments of the present disclosure, all other embodiments obtained by a person of ordinary skill in the art without creative efforts fall within the protection scope of the present disclosure.

An RF loss is an important factor affecting a linearity of RF devices. When a RF signal is transmitted in a device layer, a parasitic circuit may be formed in a substrate, and therefore, the RF signal is subject to a disturbance from the substrate, and as the frequency increases, the disturbance effect becomes more and more obvious, resulting in a relatively high RF loss.

To solve a technical problem in related technologies that a linearity of a radio frequency device is decreased due to an RF loss of the radio frequency device, and the present disclosure provides a semiconductor structure, including: a supporting substrate, a buried layer, a growth substrate, a buffer layer, and a heterojunction structure layer that are sequentially stacked; a plurality of recesses are disposed on a side, away from the supporting substrate, of the growth substrate, and the buffer layer completely covers a surface of the growth substrate. In the embodiments of the present disclosure, the recesses are disposed in the growth substrate, so that a parasitic circuit formed in the growth substrate caused by a RF signal may be blocked, to reduce a disturbance effect of the growth substrate, thereby reducing the RF loss; and the buffer layer is formed, by using epitaxial lateral overgrowth, in the recesses of the growth substrate, so that dislocation density in an epitaxial layer may be greatly reduced, to improve crystal quality, thereby improving characteristics such as electron mobility, breakdown voltage, and leakage current of a device.

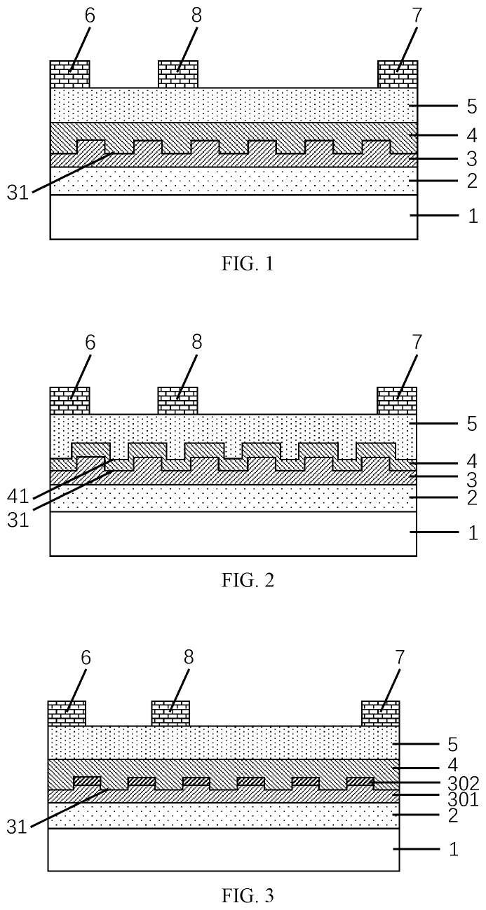

The following further describes, with reference to FIG. 1 to FIG. 10, the semiconductor structures mentioned in the present disclosure.

FIG. 1 is a schematic structural diagram of a semiconductor structure according to an embodiment of the present disclosure. As shown in FIG. 1, a semiconductor structure includes: a supporting substrate 1, a buried layer 2, a growth substrate 3, a buffer layer 4, and a heterojunction structure layer 5 that are sequentially stacked. A plurality of recesses 31 are disposed on a side, away from the supporting substrate 1, of the growth substrate 3, and the buffer layer 4 completely covers a surface of the growth substrate 3. As shown in FIG. 1, the semiconductor structure further includes: a source electrode 6 and a drain electrode 7 which are disposed on the heterojunction structure layer 5; and a gate electrode 8 disposed on the heterojunction structure layer 5 and between the source electrode 6 and the drain electrode 7.

In an embodiment, FIG. 2 is a schematic structural diagram of a semiconductor structure according to an embodiment of the present disclosure. As shown in FIG. 2, the buffer layer 4 is conformally disposed on the growth substrate 3, and the buffer layer 4 is provided with a plurality of pits 41 that are in a one-to-one correspondence with the plurality of recesses 31. The buffer layer 4 is conformally disposed on the growth substrate 3, so that a shape of an upper surface of the growth substrate 3 is retained. The epitaxial lateral overgrowth and merge growth of the heterojunction structure layer 5 starts in the plurality of pits 41, which is capable of greatly reducing dislocation density on a surface of the heterojunction structure layer 5, improving crystal quality of the heterojunction structure layer 5, thereby improving characteristics such as electron mobility, breakdown voltage, and leakage current of a device structure.

In an embodiment, FIG. 3 is a schematic structural diagram of a semiconductor structure according to an embodiment of the present disclosure. As shown in FIG. 3, the growth substrate 3 is a double layer structure, and the double layer includes a first sub-layer 301 and a second sub-layer 302 that are stacked in a direction away from the supporting substrate 1. A conductive type of the first sub-layer 301 is an n type, and a conductive type of the second sub-layer 302 is a p type; or conductive types of the first sub-layer 301 and the second sub-layer 302 are an n type, and the first sub-layer 301 has a doping concentration lower than that of the second sub-layer 302. A thickness of the second sub-layer 302 is less than a depth of each recess 31. The growth substrate 3 has a double layer with different doping concentrations or doping types, the disturbance effect of the growth substrate 3 may be further reduced, thereby reducing the RF loss.

In an embodiment, materials of the supporting substrate 1 and the growth substrate 3, include silicon. The supporting substrate 1 has (111) crystal orientation or (100) crystal orientation, and the growth substrate 3 has (111) crystal orientation. The growth substrate 3 is used to subsequently grow the buffer layer 4, to make the semiconductor structure. A (111) crystal plane of a single crystal silicon is more conducive to the epitaxial lateral overgrowth of an epitaxial structure layer made of a III-V group compound material. A thickness of the growth substrate 3 is less than 1 μm. In one embodiment a thickness of the growth substrate 3 is less than 200 nm, and when the thickness of the growth substrate 3 is relatively small and an upper semiconductor device is in a working state, a depletion layer, formed at a channel below the gate electrode, may be full of the entire growth substrate 3, thereby reducing parasitic capacitance of a device and improving device performance.

In an embodiment, a material of the buried layer 2 includes at least one of a silicon oxide, a silicon nitride, a silicon nitride oxide, or an aluminum nitride. The material of the buried layer 2 is a polar material, and the polar material refers to a material in which there is a polar bond, such as a metal oxygen or a metal nitride, a non-metal oxygen or a non-metal nitride, and a compound semiconductor. The polar bond in the polar material is exposed to a surface and used for bonding, which helps to form a relatively strong bonding interface. The material of the buried layer 2 is selected from at least one of the silicon oxide, the silicon nitride, the silicon nitride oxide, or the aluminum nitride, and the foregoing materials are not only a common insulation material but also a common polar material, and take into consideration an insulation characteristic and a bonding characteristic.

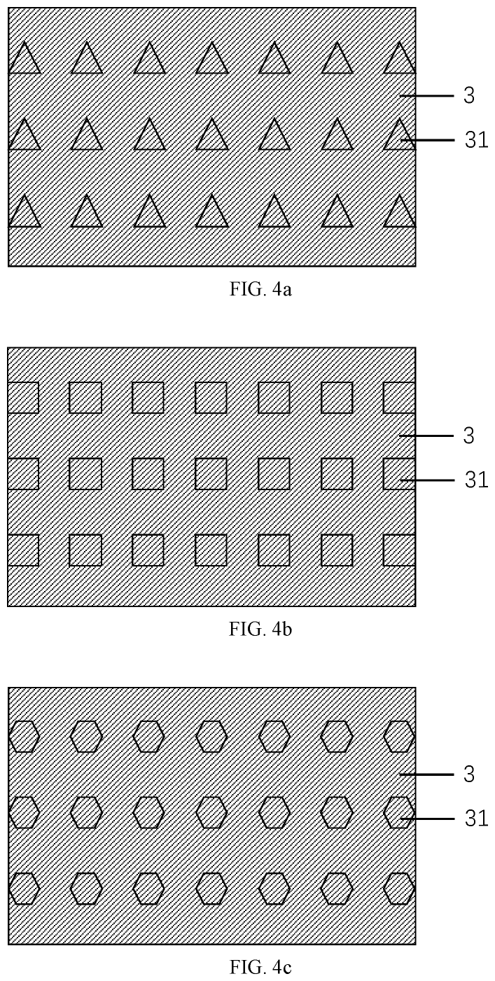

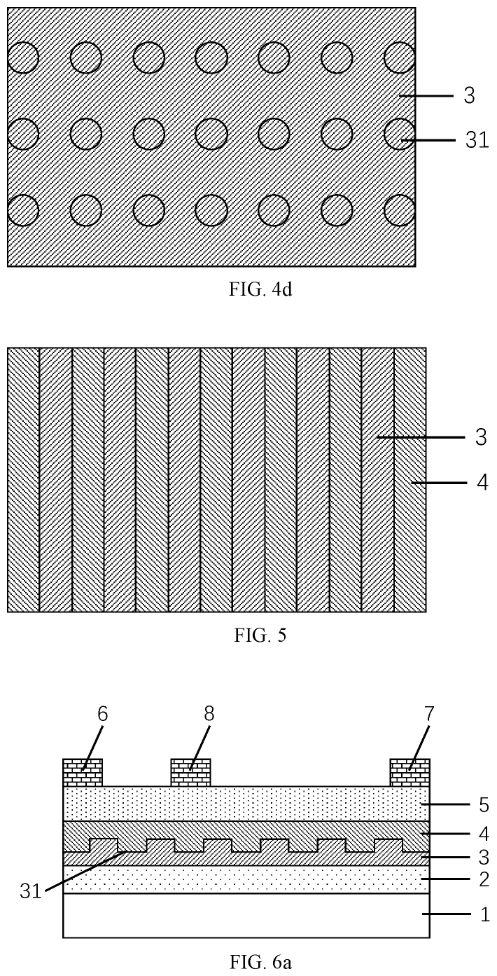

In an embodiment, FIG. 4a to FIG. 4d are top schematic views of a growth substrate according to an embodiment of the present disclosure. The plurality of recesses 31 are disposed on the side, away from the supporting substrate 1, of the growth substrate 3, depths of the recesses 31 are less than a thickness of the growth substrate 3, the plurality of recesses 31 are evenly distributed on the growth substrate 3, and shapes of projections, on a plane in which the growth substrate 3 is located, of the recesses 31 include at least one of a triangle (shown in FIG. 4a), a square (shown in FIG. 4b), a hexagon (shown in FIG. 4c), or a circle (shown in FIG. 4d), and the shapes of the projections of the recesses 31 are not specifically limited in the present disclosure.

In another embodiment, FIG. 5 is a cross-sectional schematic view of an upper surface of a growth substrate according to an embodiment of the present disclosure. The plurality of recesses 31 are disposed on the side, away from the supporting substrate 1, of the growth substrate 3, shapes of projections, on a plane in which the growth substrate 3 is located, of the plurality of recesses 31, are a plurality of strip shapes that are parallel to each other, an extension direction of each strip shape is parallel to a width direction of the gate electrode 8, and the recesses 31 are filled with the buffer layer 4. The growth substrate 3 is provided with the recesses 31 having the strip shape, so that stress in the buffer layer 4, formed in a manner of the epitaxial lateral overgrowth and the merge growth in the recesses 31 of the growth substrate 3, may be reduced, thereby quality of the subsequent epitaxial layer may be improved, including reducing dislocation density in the epitaxial layer and improving overall lattice quality of the epitaxial layer.

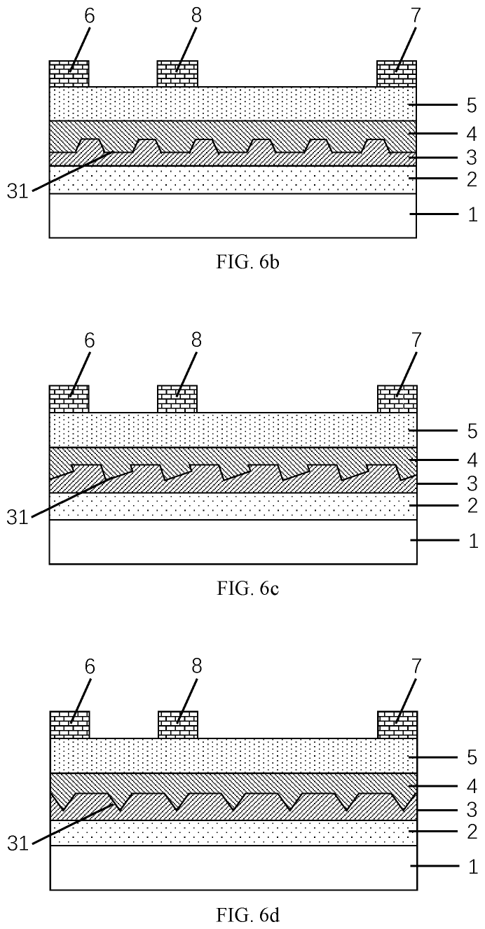

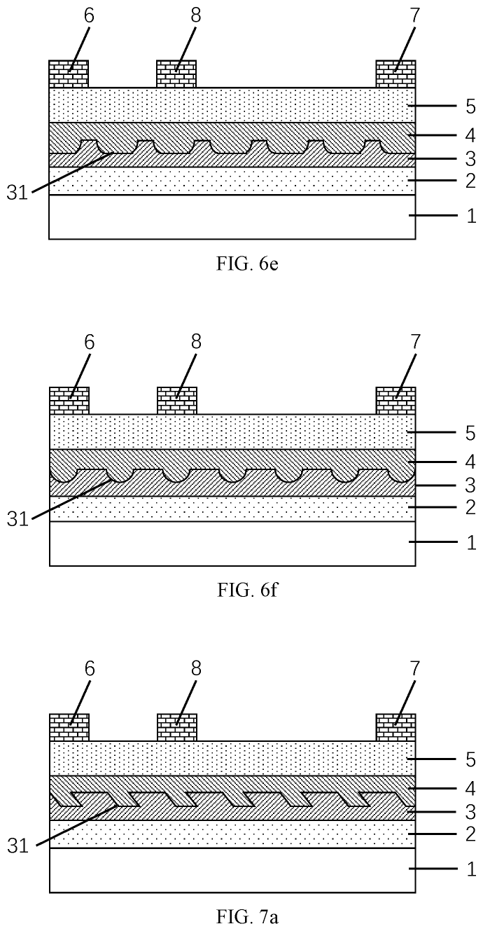

In an embodiment, FIG. 6a to FIG. 6f are schematic structural diagrams of a semiconductor structure according to an embodiment of the present disclosure. In a direction perpendicular to a plane in which the growth substrate 3 is located, cross-sectional shapes of the recesses 31 include at least one of a rectangle (shown in FIG. 6a), a trapezoid (shown in FIG. 6b), an irregular quadrilateral (shown in FIG. 6c), a triangle (shown in FIG. 6d), a bowl (shown in FIG. 6e), or an arc (shown in FIG. 6f), and the cross-sectional shapes of the recesses 31 are not specifically limited in the present disclosure.

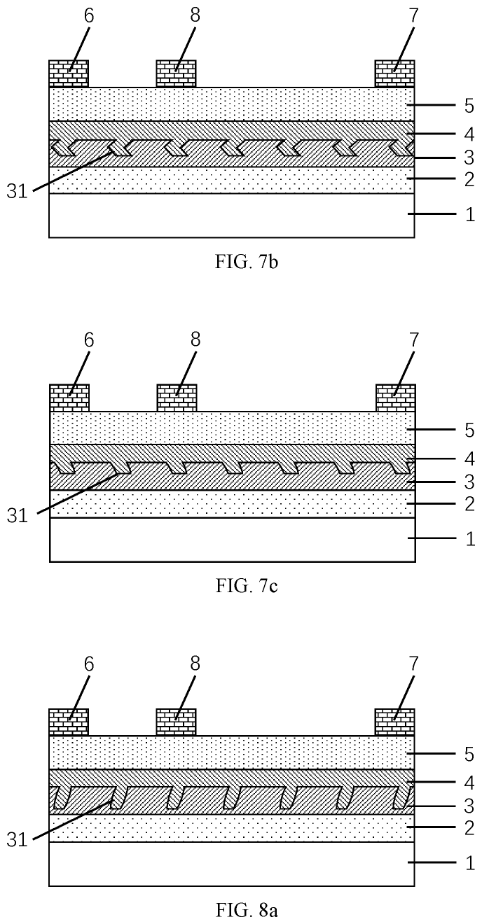

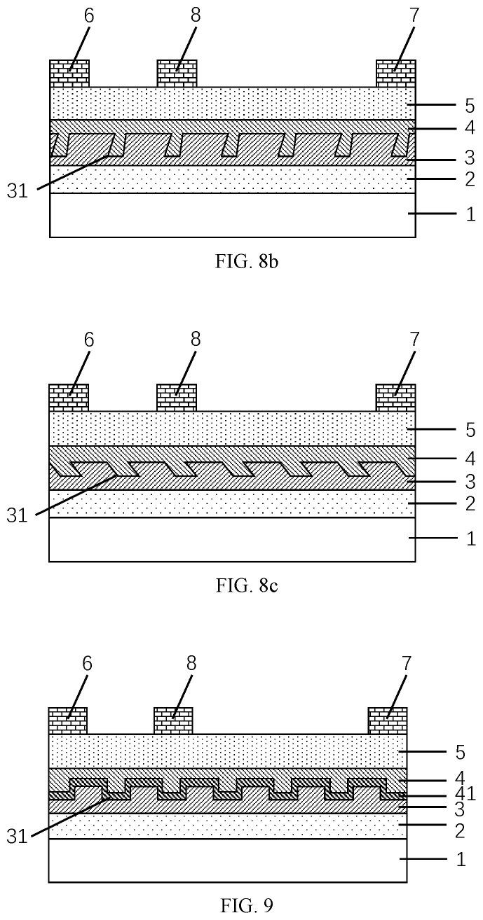

In an embodiment, FIG. 7a to FIG. 7c are schematic structural diagrams of a semiconductor structure according to an embodiment of the present disclosure. The recesses 31 are in an inclined column shape, and in a direction from the supporting substrate 1 to the growth substrate 3, a line connecting centers of a plurality of cross-sections of each recess 31 is one of a straight line (shown in FIG. 7a), a polyline (shown in FIG. 7b), or a curve (shown in FIG. 7c). FIG. 8a to FIG. 8c are schematic structural diagrams of a semiconductor structure according to an embodiment of the present disclosure. In a direction from the supporting substrate 1 to the growth substrate 3, a variation trend of areas of a plurality of cross-sections of each recess 31 includes one of the following: first increasing and then decreasing (shown in FIG. 8a), gradually decreasing (shown in FIG. 8b), or constant (shown in FIG. 8c). The recesses 31 have the inclined column shape, so that a dislocation of a material of the buffer layer 4, formed in the manner of the epitaxial lateral overgrowth in the recesses 31, terminates on a sidewall of the recesses 31, and may not continue to extend with the growth of the material of the buffer layer 4, to reduce the dislocation density in the epitaxial layer and improve the crystal quality, thereby improving the characteristics such as the electronic mobility, the breakdown voltage, and the leakage current of the device.

In an embodiment, a material of the buffer layer 4 includes a group III nitride material, the recesses 31 is completely filled with the buffer layer 4, and a surface of a side, away from the growth substrate 3, of the buffer layer 4 is a plane. The epitaxial lateral overgrowth and the merge growth of the buffer layer 4 are performed in the recesses 31, so that dislocation density on a surface of the buffer layer 4 may be greatly reduced, and crystal quality of the buffer layer 4 is improved, thereby improving the characteristics such as the electron mobility, the breakdown voltage, and the leakage current of a device structure above the buffer layer 4.

In an embodiment, FIG. 9 is a schematic structural diagram of a semiconductor structure according to an embodiment of the present disclosure. As shown in FIG. 9, a region between the buffer layer 4 and the growth substrate 3 may include a nucleation layer 41, and the nucleation layer 41 is conformally formed on the growth substrate 3 having the recesses 31. The nucleation layer 41 is conformal disposed on the growth substrate 3, a shape of an upper surface of the growth substrate 3 is retained. The epitaxial lateral overgrowth and the merge growth of the buffer layer 4 are performed in the recesses of the nucleation layer 41, to obtain the buffer layer 4 with good crystal quality on its upper surface, thereby improving crystal quality of the heterostructure layer 5 on the buffer layer 4.

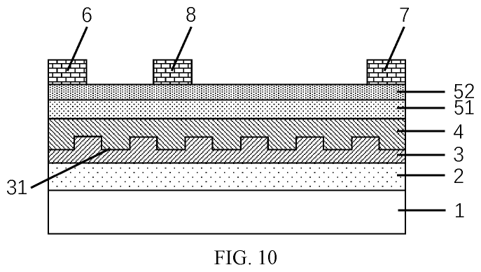

In an embodiment, FIG. 10 is a schematic structural diagram of a semiconductor structure according to an embodiment of the present disclosure. As shown in FIG. 10, in a direction away from the supporting substrate 1, the heterogeneous structure layer 5 includes a channel layer 51 and a barrier layer 52 that are stacked, and a forbidden band width of the barrier layer 52 is greater than a band gap of the channel layer 51. The channel layer 51 and the barrier layer 52 may be made of a group III nitride material, and a two-dimensional electron gas may be formed at an interface between the channel layer 51 and the barrier layer 52. In an optional solution, the channel layer 51 is a GaN layer, and the barrier layer 52 is an AlGaN layer. In another optional solution, material combination of the channel layer 51 and the barrier layer 52 may be GaN/AlN, GaN/InN, GaN/InAlGaN, GaAs/AlGaAs, GaN/InAlN, or InN/InAlN. Growth of the channel layer 51 and the barrier layer 52 may be performed in situ, or may be performed in Atomic Layer Deposition (ALD), Chemical Vapor Deposition (CVD), Molecular Beam Epitaxy (MBE), Plasma Enhanced Chemical Vapor Deposition (PECVD), Low Pressure Chemical Vapor Deposition (LPCVD), Metal-Organic Chemical Vapor Deposition (MOCVD), or a combination thereof.

The present disclosure provides a semiconductor structure, including: the supporting substrate, the buried layer, the growth substrate, the buffer layer, and the heterojunction structure layer that are sequentially stacked; the plurality of recesses are disposed on the side, away from the supporting substrate, of the growth substrate, and the buffer layer completely covers the surface of the growth substrate. In the embodiments of the present disclosure, the recesses are disposed in the growth substrate, so that the parasitic circuit formed in the growth substrate caused by the radio frequency signal may be blocked, to reduce the disturbance effect of the growth substrate, thereby reducing the RF loss; and the buffer layer is formed, by using the epitaxial lateral overgrowth, in the recesses of the growth substrate, so that the dislocation density in the epitaxial layer may be greatly reduced, to improve the crystal quality, thereby improving the characteristics such as the electron mobility, the breakdown voltage, and the leakage current of the device.

It should be understood that the term “including” and its modification used in the present disclosure are open, that is, “including but not limited to”. The term “an embodiment” represents “at least one embodiment”; and the term “another embodiment” represents “at least one further embodiment”. In this specification, a schematic description of the foregoing terms does not have to be directed to a same embodiment or example. Further, specific features, structures, materials, or characteristics described may be incorporated in an appropriate manner in any one or more embodiments or examples. In addition, without being contradictory, a person skilled in the art may combine and constitute different embodiments or examples described in this specification and features of different embodiments or examples.

The foregoing descriptions are merely exemplary embodiments of the present disclosure, and are not intended to limit the present disclosure. Any modification, equivalent replacement, or the like made within the spirit and principles of the present disclosure shall be included in the protection scope of the present disclosure.

What is claimed is:

1. A semiconductor structure, comprising:
a supporting substrate, a buried layer, a growth substrate, a buffer layer, and a heterojunction structure layer that are sequentially stacked,
wherein a plurality of recesses are disposed on a side, away from the supporting substrate, of the growth substrate, and the buffer layer completely covers a surface of the growth substrate.

2. The semiconductor structure according to claim 1, wherein the buffer layer is conformally disposed on the growth substrate, and the buffer layer is provided with a plurality of pits that are in a one-to-one correspondence with the plurality of recesses.

3. The semiconductor structure according to claim 1, wherein the buffer layer completely fills the plurality of recesses, and a surface of a side, away from the growth substrate, of the buffer layer is a plane.

4. The semiconductor structure according to claim 1, wherein the growth substrate is a double layer structure, and the double layer structure comprises a first sub-layer and a second sub-layer that are stacked in a direction away from the supporting substrate.

5. The semiconductor structure according to claim 4, wherein a conductive type of the first sub-layer is an n type, and a conductive type of the second sub-layer is a p type.

6. The semiconductor structure according to claim 4, wherein conductive types of the first sub-layer and the second sub-layer are an n type, and the first sub-layer has a doping concentration lower than that of the second sub-layer.

7. The semiconductor structure according to claim 4, wherein a thickness of the second sub-layer is less than a depth of each recess.

8. The semiconductor structure according to claim 1, further comprising:
a source electrode, a drain electrode, and a gate electrode which is disposed between the source electrode and the drain electrode, wherein the source electrode, the drain electrode, and the gate electrode are all disposed on the heterojunction structure layer.

9. The semiconductor structure according to claim 8, wherein shapes of projections, on a plane in which the growth substrate is located, of the plurality of recesses, are a plurality of strip shapes that are parallel to each other, and an extension direction of each strip shape is parallel to a width direction of the gate electrode.

10. The semiconductor structure according to claim 1, wherein the plurality of recesses are evenly distributed on the growth substrate, and shapes of projections, on a plane in which the growth substrate is located, of the plurality of recesses comprise at least one of a triangle, a square, a hexagon, or a circle.

11. The semiconductor structure according to claim 1, wherein in a direction perpendicular to a plane in which the growth substrate is located, cross-sectional shapes of the plurality of recesses comprise at least one of a rectangle, a trapezoid, an irregular quadrilateral, a triangle, a bowl, or an arc.

12. The semiconductor structure according to claim 1, wherein each recess is in an inclined column shape.

13. The semiconductor structure according to claim 12, wherein in a direction from the supporting substrate to the growth substrate, a line connecting centers of a plurality of cross-sections of each recess is one of a straight line, a polyline, or a curve.

14. The semiconductor structure according to claim 12, wherein in a direction from the supporting substrate to the growth substrate, a variation trend of areas of the plurality of cross-sections of each recess comprises one of the following: first increasing and then decreasing, gradually decreasing, or constant.

15. The semiconductor structure according to claim 1, wherein a depth of each recess is less than a thickness of the growth substrate.

16. The semiconductor structure according to claim 1, wherein materials of the supporting substrate and the growth substrate comprise silicon.

17. The semiconductor structure according to claim 1, wherein a material of the buried layer comprises at least one of a silicon oxide, a silicon nitride, a silicon nitride oxide, or an aluminum nitride.

18. The semiconductor structure according to claim 1, wherein a material of the buffer layer comprises a group III nitride material.

19. The semiconductor structure according to claim 1, further comprising: a nucleation layer disposed between the buffer layer and the growth substrate, wherein the nucleation layer is conformally formed on the growth substrate.

20. The semiconductor structure according to claim 1, wherein in a direction away from the supporting substrate, the heterogeneous structure layer comprises a channel layer and a barrier layer that are stacked, and a band gap of the barrier layer is greater than a band gap of the channel layer.
